(19) United States
(12) Patent Application Publication
(10) Pub. No.: US 2014/0044875 A1
(43) Pub. Date: Feb. 13, 2014

(54) IN-LINE DEPOSITION CHAMBER DESIGN FOR MULTI-STAGE PHYSICAL VAPOR DEPOSITION

(71) Applicants: Dong Wang, HangZhou (CN); Pingrong Yu, Santa Clara, CA (US); Xuegeng Li, Sunnyvale, CA (US); Zhiqian Su, HangZhou (CN)

(72) Inventors: Dong Wang, HangZhou (CN); Pingrong Yu, Santa Clara, CA (US); Xuegeng Li, Sunnyvale, CA (US); Zhiqian Su, HangZhou (CN)

(73) Assignee: Pu Ni Tai Yang Neng (HangZhou) Co., Limited, Hangzhou (CN)

(21) Appl. No.: 13/570,547

(22) Filed: Aug. 9, 2012

(51) Int. Cl. C23C 16/54; C23C 16/458; C23C 16/06; C23C 16/46

(52) U.S. Cl. 427/251; 118/719; 118/718

(57) ABSTRACT

An in-line multi-stage physical vapor deposition chamber is disclosed. The deposition chamber includes a cylindrical shaped main body, multiple dividers disposed within the main body and extending in radial directions to divide the interior space of the main body into multiple fan shaped zones, and a cylindrical shaped substrate holder disposed coaxially with the main body. The substrate holder is rotatable around a central axis, and individual substrates or a continuous flexible substrate is mounted on the substrate holder parallel to the central axis. Multiple metal source holders are disposed on the cylindrical sidewall of the main body in at least some of zones for mounting metal sources. Some zones are provided with heating mechanisms for heating the substrate. A load-lock chamber is connected to the main body for loading and unloading substrates into and from a first zone.

### BACKGROUND OF THE INVENTION

1. Field of the Invention

This invention relates to the field of material technology, in particular to a multi-step physical vapor deposition (PVD) apparatus of substrate processing.

2. Description of the Related Art

Depositing a layer of substance with certain features onto a substrate is a commonly used procedure in fields such as nano-material preparation and semiconductor device manufacturing. To achieve a layer of material with desired properties, the deposition procedure must be strictly followed. In industry, this depositing procedure is preferred to be carried out in high-throughput in-line chamber for purposes of cost reduction, which is a key factor for a technology to be commercialized in large volume production.

However, for some materials, the deposition procedures are difficult to finish in one chamber using an in-line approach. An example is the deposition of copper indium gallium selenide (Cu(In,Ga)Se₂, or CIGS) alloy for thin-film solar cells. Currently, the highly crystalline CIGS thin films necessary for efficient solar-to-electricity conversion are deposited on a glass/molybdenum substrate using a three-stage metal co-evaporation process (see U.S. Pat. No. 5,441,897), in which the metal sources needed, evaporation rate for each metal, and substrate temperature are different in each stage. Therefore, a conventional in-line approach, which mainly controls the substrates moving speed to achieve suitable film composition, is not feasible to deposit CIGS in one chamber. An example of the traditional in-line process is shown in FIG. 1. Here, vapor evaporated from a source 110 is deposited on a substrate 160, which is moving in the chamber. The shutter 120 can be rotated, and if necessary can block some sources. The substrate 160 can be a single piece, such as a piece of glass, or a continuous flexible substrate, such as foil.

Although CIGS absorbers can be made using procedures other than the above three-stage process, their cells efficiencies are low.

### SUMMARY OF THE INVENTION

To facilitate commercialization of technologies involving multi-stage deposition, such as the three-stage CIGS fabrication process mentioned above, a chamber design that is able to finish the multi-stage PVD as an in-line process is described in this disclosure. According to embodiments of the present invention, a cylindrical vacuum chamber is divided into several zones. Each zone, with specific evaporation sources and evaporation rate, is responsible for a single deposition stage. The zones for substrate cooling and loading/unloading are also included. The substrates are moved through different zone to complete the multi-stage deposition process.

Additional features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, the present invention provides an in-line multi-stage physical vapor deposition chamber, which includes: a main body having a cylindrical shaped sidewall defining an interior space; a plurality of dividers disposed in the interior space and extending in radial directions to divide the interior space into a plurality of zones; a substrate holder having a cylindrical shape disposed coaxially with the main body in the interior space, the substrate holder being rotatable around a central axis, for mounting substrates parallel to the central axis; and a plurality of metal source holders disposed on the sidewall of the main body in at least some of the plurality of zones for mounting metal sources.

The in-line multi-stage physical vapor deposition chamber may further include a load-lock chamber connected to a first one of the plurality of zones for loading substrates onto and unloading substrates from the substrate holder. The load-lock chamber may include a loading arm for loading individual pieces of substrate onto the substrate holder. Or, the deposition chamber may include an unwinding device for holding a continuous flexible substrate before the substrate is loaded onto the substrate holder, and a winding device for holding the substrate after the substrate is unloaded from the substrate holder. The substrate holder rotates continuously or intermittently to advance the substrates or substrate.

In another aspect, the present invention provides an in-line multi-stage physical vapor deposition method, which includes: providing a deposition chamber having a plurality of zones formed by a cylindrical shaped main body and a plurality of dividers within the main body; mounting a plurality of substrates or a continuous flexible substrate on a cylindrical shaped substrate holder disposed within the main body, the substrates or substrate being mounted parallel to a central axis of the substrate holder; rotating the substrate holder around the central axis to advance the substrates or substrate successively to different zones of the deposition chamber; and providing a plurality of metal source on a sidewall of the main body in at least some of the plurality of zones to deposit metals onto the substrates or substrate located within such zones.

The substrates may be individual pieces of substrate, and the method may further include unloading a piece of substrate from the substrate holder and loading another piece of substrate onto the substrate holder using a loading arm located in a load-lock chamber connected to the main body of the deposition chamber. Or, the substrate may be a continuous flexible substrate, and the method may further include: holding the continuous substrate on an unwinding device;

loading the substrate from the unwinding device onto the substrate holder; and unloading the substrate from the substrate holder onto a winding device. The substrate holder may be rotated continuously or intermittently to advance the substrates or substrate.

It is to be understood that both the foregoing general description and the following detailed description are exemplary and explanatory and are intended to provide further explanation of the invention as claimed.

### BRIEF DESCRIPTION OF THE DRAWINGS

FIG. 1 schematically illustrates a conventional in-line deposition process.

FIG. 2 is a perspective view to a cylindrical deposition chamber according to an embodiment of the present invention.

FIG. 3 is a side cross sectional view of the deposition chamber of FIG. 2 through the central axis and two evaporation zones.

FIG. 4 is a side cross sectional view of the deposition chamber of FIG. 2 through the central axis, one evaporation zone, the substrate loading zone, and the load-lock chamber.

FIG. 5 is a perspective view of the substrate holder of the deposition chamber of FIG. 2.

FIG. 6 is a top cross sectional view of a cylindrical deposition chamber for use with a flexible continuous substrate according to another embodiment of the present invention.

### DETAILED DESCRIPTION OF THE PREFERRED EMBODIMENTS

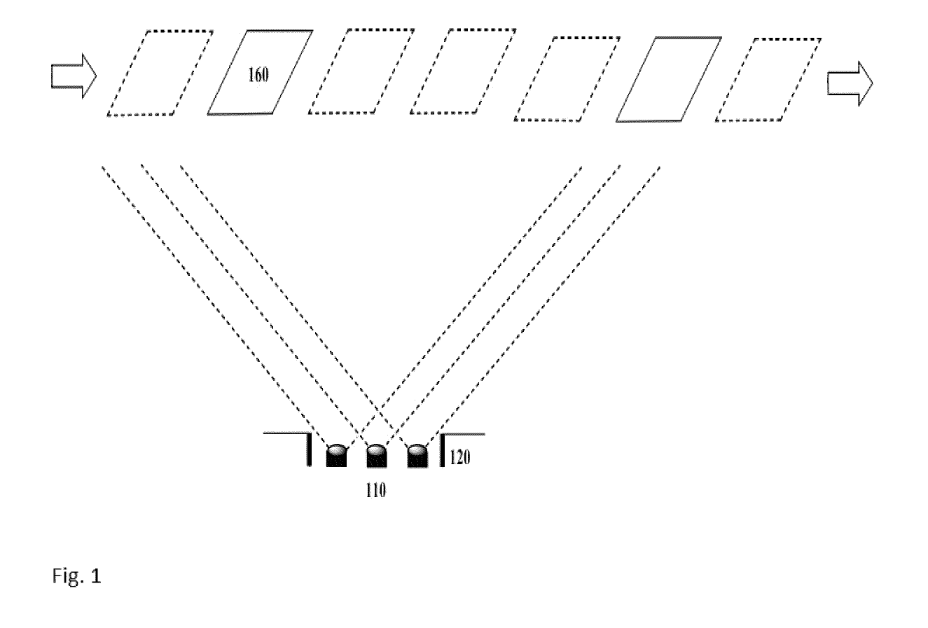

A multi-zone chamber design that accomplishes multi-stage PVD in an in-line process in a single chamber is disclosed herein. The substrate moves through different zones within the chamber to undergo different deposition stages sequentially. At any given moment, multiple areas of the substrate or multiple substrates are in the chamber but reside in different zones, i.e. in different stages of the deposition process. A conventional in-line process is schematically shown in FIG. 1. Vapor evaporated from the sources 110 is deposited onto the substrates 160 while they are moving inside the chamber. Depending on the film composition, the sources may contain the same or different substances. A shutter 120 is moveable (e.g. rotatable) to shield some of the sources if needed. The substrates 160 may be the discrete pieces, such as glass, or a flexible continuous sheet, such as a foil. Although the vapor composition and concentration vary for different regions within the chamber, the final deposited film is highly uniform because all substrates (or all areas of the continuous substrate) move at the same constant speed and passed through the same regions of the chamber. However, for a multi-stage process that requires different sources for each step, either a much larger chamber or multiple chambers are needed. In both cases, the vacuum and substrate handling, temperature regulation, and extra load-lock feature are challenging and tend to dramatically increase the production cost.

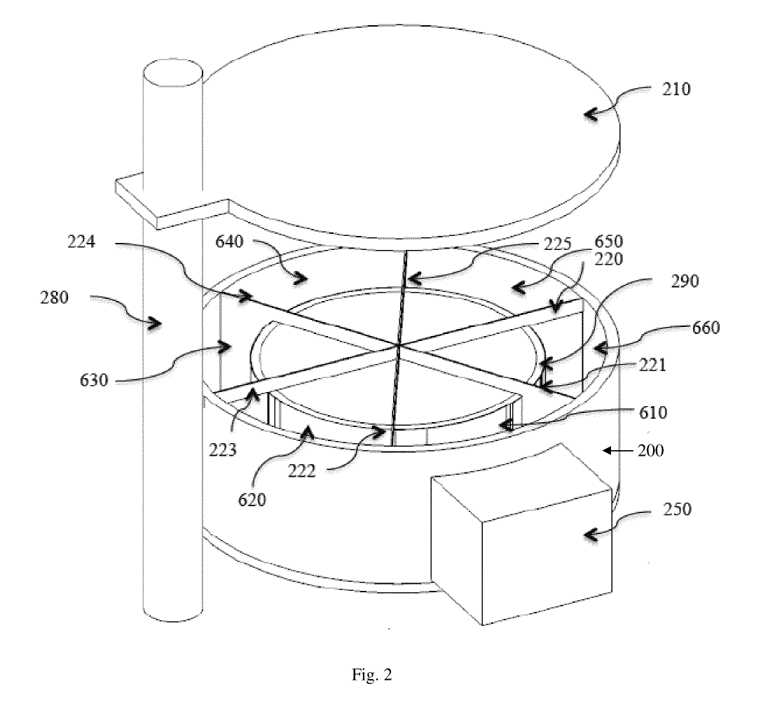

According to embodiments of the present invention, a cylindrical vacuum chamber is provided to complete multi-stage deposition using an in-line approach without adding cost and technical challenges. As an example, a chamber for three-stage CIGS deposition is shown in FIGS. 2-5. However, similar chamber designs are applicable to other deposition processes.

As shown in these figures, the deposition chamber includes a cylindrical shaped main body 200 and a cover 210. The cover 210 can be elevated by lifting shaft 280 so that the parts inside the chamber can be serviced or replaced. A cooling mechanism is provided for cooling the deposition chamber; for example, cooling water can circulate in inner channels within walls of the main body 200 to prevent overheating during evaporation. The interior space enclosed by the cylindrical main body 200 is divided into several fan shaped zones 610-660 by shields or dividers 220-225 that extend in the radial directions. A substrate holder 290 is located in the chamber with a rotation shaft 240 connected to its center to rotate the substrate holder.

The number of zones and the task performed in each zone depend on the recipe at each stage in the whole deposition process. In the case of depositing CIGS film as shown in FIG. 2, zone 610 is a loading/unloading zone for loading/unloading the substrates via the attached load-lock chamber 250; zone 620 is for pre-heating the substrate; zone 630, 640, 650 are the three deposition zones for the three deposition stages, respectively; zone 660 allows the substrate and the deposited film to cool down before they are transferred to the load-lock chamber 250 in zone 610. A description of the substrate's history inside the chamber is provided to demonstrate how the in-line process proceeds.

At the beginning (time point zero), in zone 610, a substrate with deposited film is unloaded to the load-lock chamber 250, and a substrate to be processed is loaded onto the substrate holder 290 from the load-lock chamber. At a first time point (e.g. 15 minutes), the rotation shaft 240 rotates clockwise by 60 degree; as a result, the substrate moves into zone 620, where it is preheated to 440° C. At a second time point (e.g. 30 minutes), the rotation shaft 240 rotates clockwise by 60 degree, and the substrate is now in zone 630, where (In,Ga)ₓSe_{y} is deposited. At a third time point (e.g. 45 minutes), the rotation shaft 240 rotates clockwise by 60 degree so that the substrate is in zone 640, where Cu_{R}Se is deposited. At a fourth time point (e.g. 60 minutes), the rotation shaft 240 rotates clockwise by 60 degree so that the substrate is in zone 650, where (In,Ga)ₓSe_{y} is deposited again. At a fifth time point (e.g. 75 minutes), the rotation shaft 240 rotates clockwise by 60 degree so that the substrate is in zone 660, where the substrate naturally cools down to below 200° C. At a sixth time point (e.g. 90 minutes), the rotation shaft 240 rotates clockwise by 60 degree so that the substrate goes back to zone 610, where substrate is unloaded to the load-lock chamber 250. By following the above procedure, a CIGS film is deposited on one substrate every 15 minutes. The use of 15-minute time interval in the above example is based on the original three-stage recipe described as in U.S. Pat. No. 5,441,897 since the deposition time for each stage is 15 minutes. This time interval may be shorter or longer depending on the vapor evaporation rates in each stage and the desired final film thickness.

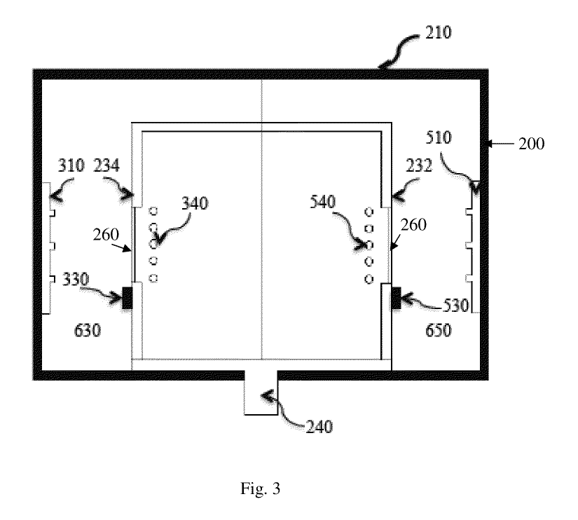

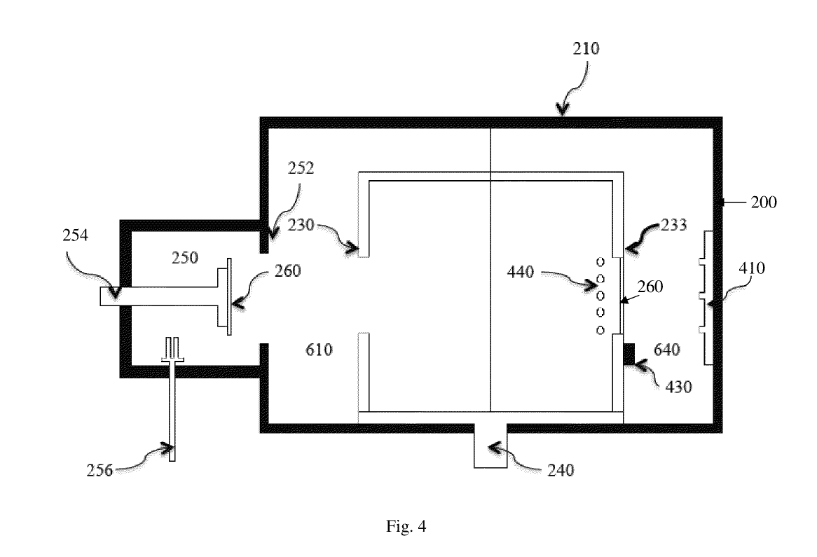

FIG. 3 is a cross sectional view of the cylindrical deposition chamber through the central axis. This cross section goes through two evaporation zones 630 and 650. Metal sources that are present in each zone are determined by which stage that zone is used for. For example, zones 630 and 650 are used for the first and third stage, respectively, which are the deposition of (In,Ga)ₓSe_{y}; therefore the metal sources are indium, gallium, and selenium. As shown in FIG. 3, evaporating metal sources are provided on the cylindrical sidewall of the chamber in a linear arrangement. Here, the metal sources mounted on source holders 310 and 510 are the central ones of multiple (e.g. three) side-by-side sources. In zone 640 (see FIG. 4) which is for the second stage deposition, the metal sources mounted on source holder 410 are copper and selenium for the Cu_{R}Se deposition occurring in this stage. To achieve high film uniformity throughout the substrate in each zone, the number of sources for each metal, the shape of the sources, and their positions may be configured accordingly. The arrangement of the sources shown in FIG. 3 is merely a schematic illustration; it may not depict the optimized configuration.

Each metal source may be accompanied by a shutter to shield the source as desired. The shutters are useful when calibrating the vapor deposition rate of one source by crystals analyzers 330 and 530, where other vapor sources need to be shielded to prevent interference. More importantly, the shutters are necessary when the required vapor deposition time is shorter than the interval time between each rotation of the substrate holder.

As shown in FIG. 3, heaters 340 and 540 may be provided behind the substrate 260. For instance, in zone 630 where the first stage deposition occurs, the substrate is heated at 440° C. The heaters may be any suitable heating mechanisms, such as infrared lamps or electrical heating plates.

FIG. 4 is another cross sectional view of the cylindrical deposition chamber through the central axis. This cross section goes through the substrate loading zone 610. After the three-stage deposition is completed and the substrate is cooled in zone 660, the rotation shaft 240 rotates to transfer the finished substrate to zone 610. The small load-lock chamber 250 is maintained at the same vacuum pressure as the deposition chamber. Then, the loading gate 252 on the main body 200 is open to allow an arm 254 to unload the finished substrate 260 from the area 230 of the substrate holder. Subsequently, another arm 256 supplies a new substrate, which is then loaded onto the holder by the arm 254, and the loading gate 252 is then closed.

A gas such as nitrogen or an inert gas is introduced into the load-lock chamber 250 so that the finished substrate with film can be taken out to the atmosphere and the new substrate can be reloaded into the load-lock chamber. A vacuum is then created in the load-lock chamber to the same pressure as the deposition chamber to get ready for the next unloading/loading cycle.

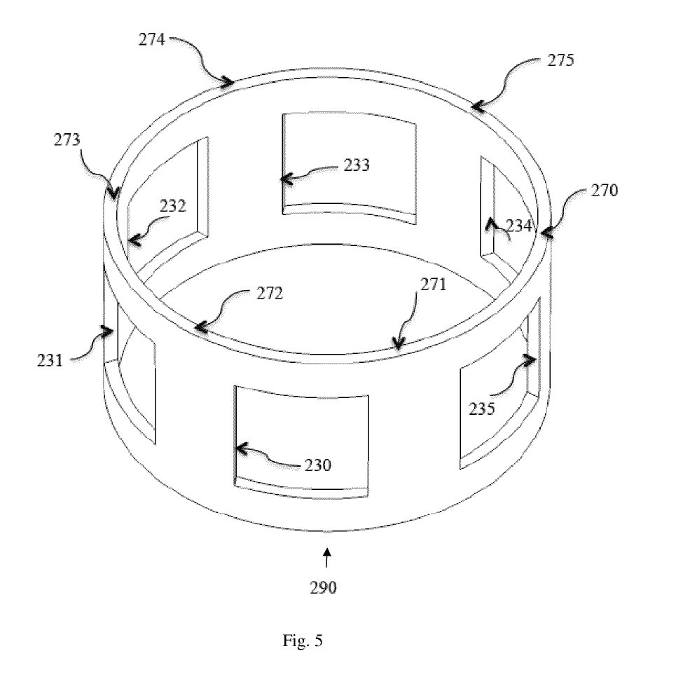

FIG. 5 illustrates the substrate holder 290. The substrate holder has a generally cylindrical shape disposed coaxially with the main body 200, and is rotatable around the central axis by rotating the rotation shaft 240. Windows 230-235 are used for substrate mounting, and the substrates can be fixed by holding sections 270-275 located around the windows. The number of windows corresponds to the number of zones in the chamber, and the shape of the windows depends on the shape of the substrate. The substrates are mounted vertically, i.e., parallel to the central axis of the chamber, and overlap with the windows 230-235 (see also FIGS. 3 and 4). As shown in FIGS. 3 and 4, the metal sources are mounted by holders 310, etc. on the cylindrical sidewall of the chamber and face the vertical substrates.

In general, the in-line single-chamber according to embodiments of the present invention is suitable for all multi-stage physical vapor deposition process. Each zone operates independently as an individual chamber. The number of zones may vary depending on the number of stages in the deposition; the duration that the substrate stays in each zone is changeable; the heating mechanisms and sources evaporation rates in each zone are programmable; the sources arrangement is independent in each zone; there is no limitation on the shape and the size of the substrate as long as the substrate holders have enough physical strength. The term “substrate” in this disclosure refers not only to the materials that can be used as substrate, but also to the substrate materials equipped with frames or shadow masks.

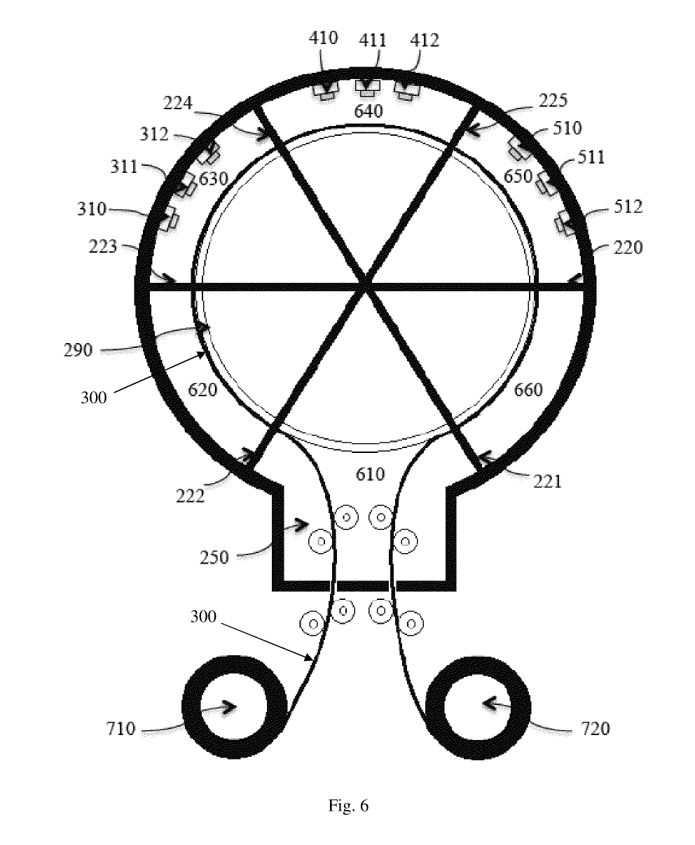

FIG. 6 is a top cross sectional view, taken along the direction of the central axis, showing a cylindrical in-line deposition chamber for use with a flexible continuous substrate sheet for multi-stage physical vapor deposition according to another embodiment of the present invention. The continuous substrate 300 drawn from unwinding device (roller) 710 goes into zone 610 through the load-lock chamber 250. Then the foil substrate is loaded (wounded) onto the substrate holder 290 which has a cylindrical shape. The substrate 300 is mounted vertically on the holder 290, i.e., parallel to the central axis of the chamber and the substrate holder. The substrate holder 290 is rotated (e.g. clockwise) by a rotation shaft. The rotation shaft is not shown in FIG. 6, but it may have a similar structure as the rotation shaft 240 of FIGS. 3 and 4. The rotation may be continuous at a relatively slow speed of advancement, e.g. 90 minutes per revolution; or it may be intermittent, e.g., it stops for 15 minute intervals and rotates by 60 degrees at the end of each interval. The substrate 300 mounted on the holder 290 goes through zones 620, 630, 640, 650, and 660 in turn; it is preheated in zone 620, deposited with (In,Ga)ₓSe_{y} in zone 630, deposited with CuₓSe in zone 640, deposited with (In,Ga)ₓSe_{y} in zone 650 again, and then naturally cooled down to below 200° C. in zone 660. After this process, the substrate 300 finally goes back to zone 610, where it is unloaded from holder 290. Then the substrate goes out of the chamber 250 and is collected by the winding device (roller) 720.

In the device shown in FIG. 6, the winding and unwinding rollers 720, 710 are located outside of the load-lock chamber 250. Additional rollers are provided to guide the substrate as appropriate. The slits where the flexible substrate enters and leaves the load-lock chamber are designed such that the vacuum in the load-lock chamber and the deposition chamber is maintained. In an alternative structure, the load-lock chamber is eliminated; the substrate directly enters the zone 610 of the deposition chamber from the unwinding roller 710, and leaves the zone 610 to be wound on the winder roller 720. In another alternative structure, the winding roller 720 and unwinding roller 710 are located inside the load-lock chamber 250. The metal sources provided in various zones of the embodiment of FIG. 6 may be similar to those provided in the embodiment in FIGS. 2-5. For example, in zone 630, metal sources mounted on source holders 310, 311 and 312 are indium, gallium, and selenium. Metal sources mounted on source holders 410 411 and 412 in zone 640 are copper and selenium, and sources mounted on source holders 510, 511 and 512 in zone 650 are also indium, gallium, and selenium. It will be apparent to those skilled in the art that various modification and variations can be made in the in-line deposition chamber of the present invention without departing from the spirit or scope of the invention. Thus, it is intended that the present invention cover modifications and variations that come within the scope of the appended claims and their equivalents.

1. An in-line multi-stage physical vapor deposition chamber, comprising:
a main body having a cylindrical shaped sidewall defining an interior space;
a plurality of dividers disposed in the interior space and extending in radial directions to divide the interior space into a plurality of zones;
a substrate holder having a cylindrical shape disposed coaxially with the main body in the interior space, the substrate holder being rotatable around a central axis, for mounting substrates parallel to the central axis;
wherein each of the plurality of dividers is planar-shaped and extends from the sidewall to a radial position that is between the central axis and the substrate holder, wherein each of the plurality of dividers further extends in a direction parallel to the central axis, and
a plurality of metal source holders disposed on an inside surface of the sidewall of the main body in at least some of the plurality of zones for mounting metal sources.

2. The in-line multi-stage physical vapor deposition chamber of claim 1, wherein the substrate holder has a plurality of windows and a plurality of substrate holding sections located around the windows, wherein a number of the windows is the same as a number of zones.

3. The in-line multi-stage physical vapor deposition chamber of claim 1, further comprising a heating mechanism disposed in at least one of the plurality of zones for heating the substrate mounted on the substrate holder.

4. The in-line multi-stage physical vapor deposition chamber of claim 1, further comprising a plurality of shutters associated with the metal source holders for shielding the metal sources mounted on the metal source holders.

5. The in-line multi-stage physical vapor deposition chamber of claim 1, further comprising a load-lock chamber connected to a first one of the plurality of zones for loading substrates onto and unloading substrates from the substrate holder.

6. The in-line multi-stage physical vapor deposition chamber of claim 1, wherein the load-lock chamber comprises a loading arm for loading individual pieces of substrate onto the substrate holder.

7. The in-line multi-stage physical vapor deposition chamber of claim 1, further comprising an unwinding device for holding a continuous flexible substrate before the substrate is loaded onto the substrate holder, and a winding device for holding the substrate after the substrate is unloaded from the substrate holder.

8. The in-line multi-stage physical vapor deposition chamber of claim 7, wherein the substrate holder rotates continuously to advance the substrate.

9. The in-line multi-stage physical vapor deposition chamber of claim 1, wherein the substrate holder rotates intermittently to advance the substrates or substrate.

10. The in-line multi-stage physical vapor deposition chamber of claim 1, further comprising:
a cover disposed above the main body for covering the interior space; and
a lifting mechanism for lifting the cover.

11. The in-line multi-stage physical vapor deposition chamber of claim 1, further comprising a cooling mechanism surrounding the main body.

12. An in-line multi-stage physical vapor deposition method, comprising:
providing a deposition chamber having a plurality of zones formed by a cylindrical shaped main body and a plurality of dividers within the main body;
mounting a plurality of substrates or a continuous flexible substrate on a cylindrical shaped substrate holder disposed within the main body, the substrates or substrate being mounted parallel to a central axis of the substrate holder;
rotating the substrate holder around the central axis to advance the substrates or substrate successively to different zones of the deposition chamber; and
providing a plurality of metal source on a sidewall of the main body in at least some of the plurality of zones to deposit metals onto the substrates or substrate located within such zones.

13. The in-line multi-stage physical vapor deposition method of claim 12, further comprising:
heating the substrate located within one of the zones.

14. The in-line multi-stage physical vapor deposition method of claim 12, wherein the substrates are individual pieces of substrate, the method further comprising:
unloading a piece of substrate from the substrate holder and loading another piece of substrate onto the substrate holder using a loading arm located in a load-lock chamber connected to the main body of the deposition chamber.

15. The in-line multi-stage physical vapor deposition method of claim 12, wherein the substrate is a continuous flexible substrate, the method further comprising:
holding the continuous substrate on an unwinding device;
loading the substrate from the unwinding device onto the substrate holder; and
unloading the substrate from the substrate holder onto a winding device.

16. The in-line multi-stage physical vapor deposition method of claim 15, wherein the substrate holder is rotated continuously to advance the substrate.

17. The in-line multi-stage physical vapor deposition method of claim 12, wherein the substrate holder is rotated intermittently to advance the substrates or substrate.
